(19) United States
(12) Patent Application Publication
(10) Pub. No.: US 2016/0062829 A1
(43) Pub. Date: Mar. 3, 2016

(54) SEMICONDUCTOR MEMORY DEVICE

(71) Applicant: KABUSHIKI KAISHA TOSHIBA, Minato-ku (JP)

(72) Inventors: Akinori HARASAWA, Kunitachi (JP); Hiroyuki MORO, Hachioji (JP)

(73) Assignee: KABUSHIKI KAISHA TOSHIBA, Minato-ku (JP)

(21) Appl. No.: 14/608,715

(22) Filed: Jan. 29, 2015

Related U.S. Application Data
(60) Provisional application No. 62/044,002, filed on Aug. 29, 2014.

(51) Int. Cl. G06F 11/10; H03M 13/29; G11C 29/52

(52) U.S. Cl. CPC G06F 11/1068; G11C 29/52; H03M 13/2906

(57) ABSTRACT

According to one embodiment, a semiconductor memory device includes a generator to generate an error correction code. The generator includes a first encoder to calculate a first error correction code, a second encoder to calculate a second correction code, and an operation part to operate the first error correction code and the second error correction code.

### CROSS-REFERENCE TO RELATED APPLICATIONS

This application claims the benefit of U.S. Provisional Application No. 62/044,002, filed Aug. 29, 2014, the entire contents of which are incorporated herein by reference.

### FIELD

Embodiments described herein relate generally to a semiconductor memory device.

### BACKGROUND

Semiconductor memory devices utilizing an error correction code for better reliability of stored data have been provided.

### BRIEF DESCRIPTION OF THE DRAWINGS

FIG. 1 shows an example of the whole structure of a semiconductor memory device of first and second embodiments.

FIG. 2A is an example of the data format in the first and second embodiments.

FIG. 2B is another example of the data format in the first and second embodiments.

FIG. 3 is a block diagram which shows a structural example of an error correction code generator of the first embodiment.

FIG. 4 shows an example of data for one logical page stored in a nonvolatile memory medium of the first embodiment.

FIG. 5 is a flowchart which shows an example of a generating process of ECC parity relative to a data which requires a padding read process in the first embodiment.

FIG. 6 is a block diagram which shows a structural example of an error correction code generator of the second embodiment.

FIG. 7 is a flowchart which shows an example of a generating process of ECC parity relative to a data which requires a padding read process in the second embodiment.

FIG. 8 is a flowchart which shows the example of the generating process of ECC parity relative to a data which requires a padding read process in the second embodiment.

FIG. 9 shows an example of a schematic structure of a device in which the semiconductor memory device is incorporated.

### DETAILED DESCRIPTION

In general, according to one embodiment, a semiconductor memory device includes a generator to generate an error correction code, the generator including a first encoder to calculate a first error correction code, a second encoder to calculate a second correction code, and an operation part to operate the first error correction code and the second error correction code.

In this specification, a single element may be referred to by different expressions in some cases. These expressions are for the sake of exemplification and do not limit the terms of the element thereto. Furthermore, an element referred to by a single expression may be referred to by other expressions.

Note that, in this specification, calculation means acquiring an encode result, that is, an error correction code from predetermined operations performed by first and second encoders.

Furthermore, in this specification, operation means acquiring a certain value (an exclusive OR in the following embodiments) based on two encode results from an operation part using a predetermined formula.

Hereinafter, embodiments are explained with reference to the accompanying drawings.

### First Embodiment

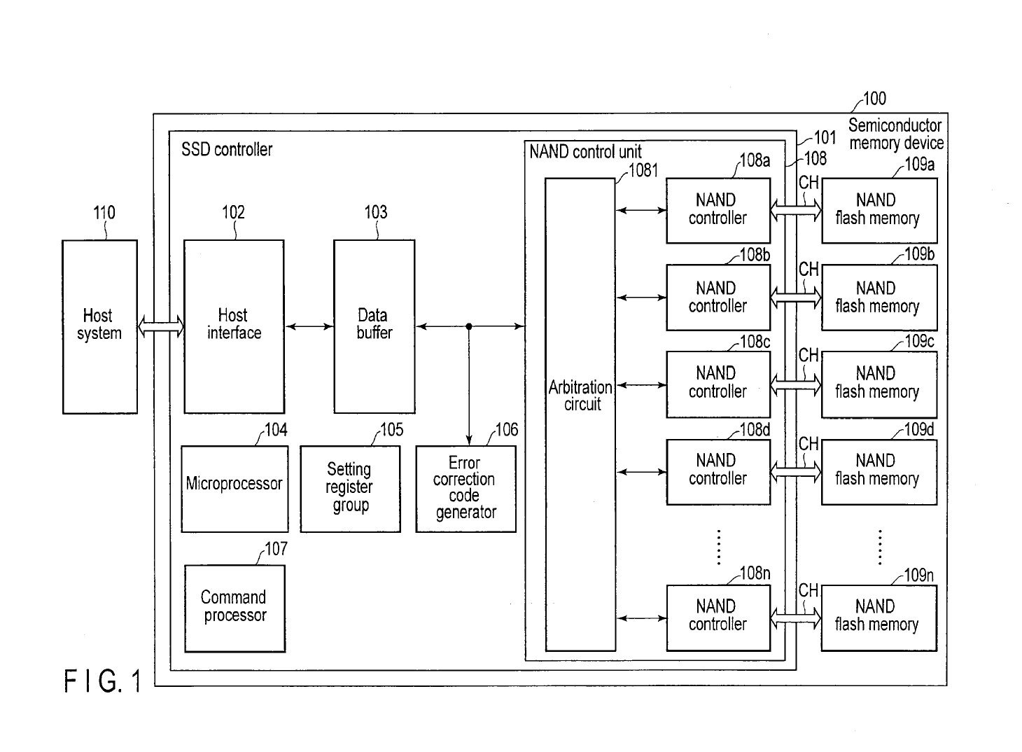

FIG. 1 shows the entire structure of a semiconductor memory device 100.

As shown in FIG. 1, the semiconductor memory device 100 is communicably connected to a host system 110 (for example, an information processing device such as a personal computer). The semiconductor memory device 100 receives various commands from the host system 110 to perform processes based on the received commands. For example, when receiving a write command, the semiconductor memory device 100 performs a write process of a write data based on the command. Note that the semiconductor memory device 100 is solid state drive (SSD) in the first embodiment.

Furthermore, the semiconductor memory device 100 includes NAND flash memories 109a, 109b, . . . , 109n and an SSD controller 101. Here, NAND flash memories 109a, 109b, . . . , 109n are a nonvolatile memory system of a memory unit of the semiconductor memory device 100.

NAND flash memories 109a, 109b, . . . , 109n are each connected to the SSD controller 101.

The SSD controller 101 includes a host interface 102 connected to the host system 110 and NAND control unit 108 which is a control unit connected to each of NAND flash memories 109a, 109b, . . . , 109n. The host interface 102 is an interface conformant with, for example, the Serial Advanced Technology Attachment (SATA) standard or PCI express (PCIe) standard.

In addition, the SSD controller 101 includes a data buffer 103, microprocessor 104, setting register group 105, error correction code generator 106 which is a generator, and command processing unit 107.

The data buffer 103 buffers a data transferred/received between the host interface 102 and NAND control unit 108 temporarily.

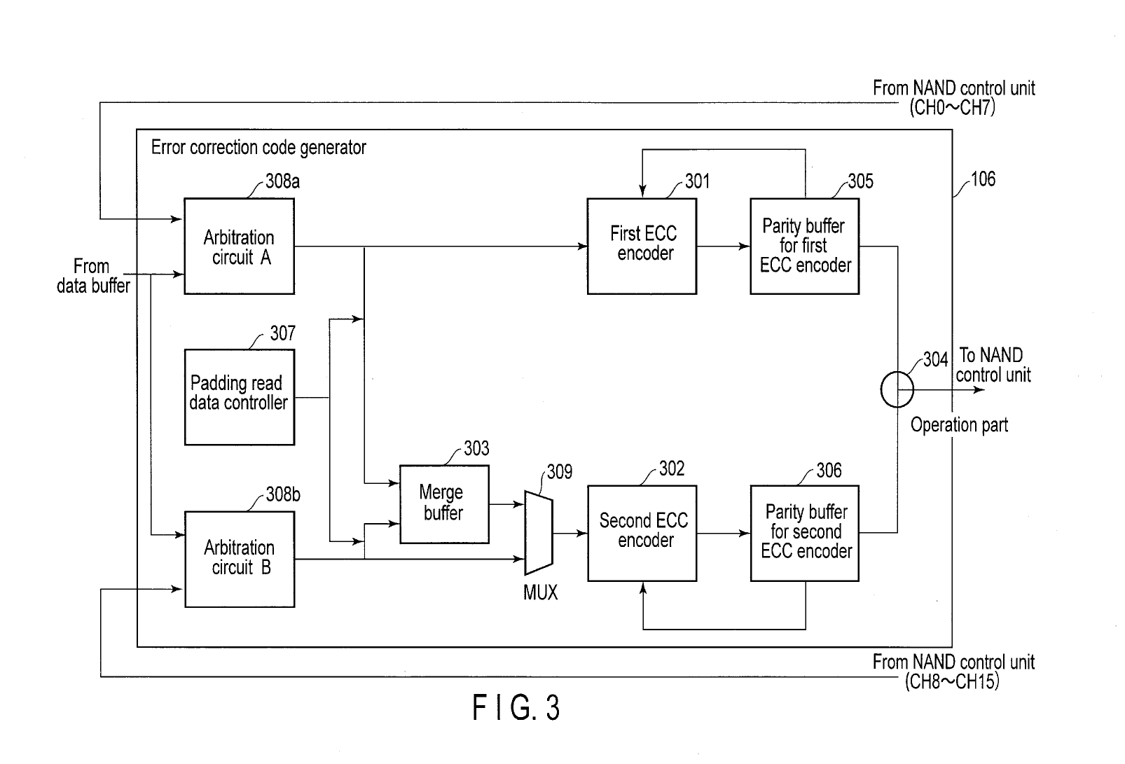

The error correction code generator 106 is provided between the data buffer 103 and the NAND control unit 108. The error correction code generator 106 generates error correction code (ECC) parity (error correction code) of the data transmitted from the host system 100 to NAND control unit 108 via the host interface 102 and the data buffer 103. The error correction code generator 106 is described in detail in the latter part (cf. FIG. 3).

The microprocessor 104 is composed of a CPU, ROM, RAM, and the like. The microprocessor 104 controls the devices in the semiconductor memory device 100 collectively.

The setting register group 105 stores various setting values of the semiconductor memory device 100. Various setting values of the setting register group 105 are set based on the instruction from the microprocessor 104.

The command processing unit 107 processes the command received from the host system 110 via the host interface 102.

Note that the host interface 102, setting register group 105, command processing unit 107, and NAND control unit 108 are, respectively, connected to a system bus (not shown) of the microprocessor 104.

NAND control unit 108 reads/writes a data from/to NAND flash memories 109a, 109b, . . . , 109n. The data read/write from/to each of NAND flash memories 109a, 109b, . . . , 109n are performed via channels CH0 to CH15 (a plurality of channels CH).

Furthermore, NAND control unit 108 is connected to the data buffer 103, setting register group 105, error correction code generator 106, and command processing unit 107. Note that a line between NAND control unit 108 and setting register group 105 and a line between NAND control unit 108 and command processing unit 107 are omitted in FIG. 1.

NAND control unit 108 includes NAND controllers 108a, 108b, . . . , 108n and an arbitration circuit 1081.

NAND controllers 108a, 108b, . . . , 108n control respective NAND flash memories 109a, 109b, . . . , 109n individually in relation to an operation such as programming, reading, and erasing.

The arbitration circuit 1081 is connected to each of NAND control units 108a, 108b, . . . , 108n which individually adjusts the timing of an operation such as programming, reading, and erasing.

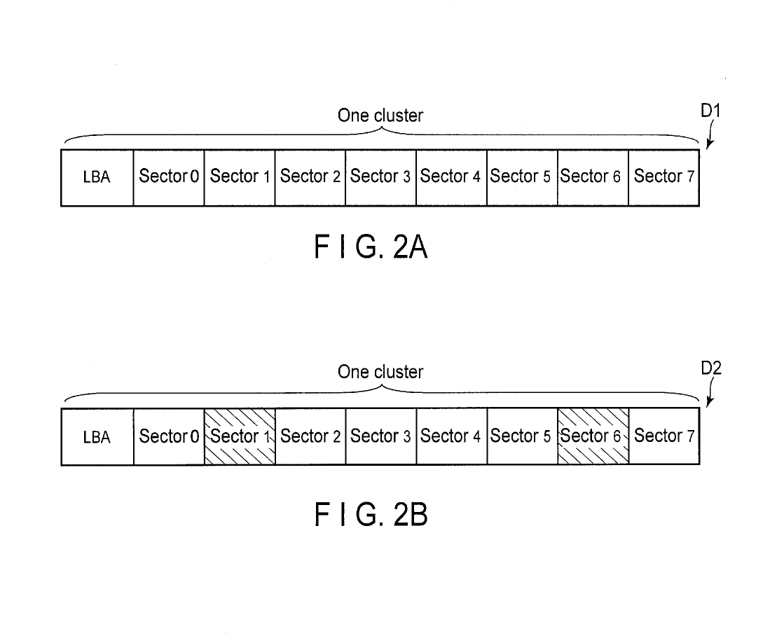

FIG. 2A and FIG. 2B show an example of data format in the first embodiment.

As can be understood from data D1 in FIG. 2A, one data cluster is composed of a logical block address (LBA) representing a logical address of the cluster and eight data parts of sectors 0 to 7 each having the same data length. Here, the data cluster is a minimum logical unit on a disk allocated to a file of a file system. Furthermore, the sector is a memory unit to memorize data in the disk. For example, if a sector is 512 bytes, a cluster is 4 kilobytes (KB).

If one data cluster linked with a certain LBA includes all of sectors 0 to 7 as shown in data D1, the data cluster is determined to be data from which ECC parity can be generated by the error correction code generator 106.

Contrary, data D2 shown in FIG. 2B is a data cluster from which no ECC parity can be generated.

As a data cluster linked with a certain LBA, data D2 is now given. As shown in the Figure, data D2 is with sector 0, sectors 2 to 5, and sector 7 received from the host system 110, that is, the data cluster lacks data of sector 1 and sector 6. Note that unreceived data of sector 1 and sector 6 are hatched in FIG. 2B.

Then, if the host system 110 notifies a completion of transfer of the data linked with the LBA while data D2 is present, the data cluster is determined to be data with incomplete set of sectors (that is, lacking sectors 1 and 6). From such incomplete data (unencodable data), the error correction code generator 106 cannot generate ECC parity. The reason is described later.

In order to modify data D2 in such a condition to generate ECC parity therefrom, data for sector 1 and sector 6 are required. That is, a padding read process is required to pad the data in sector 1 and sector 6.

Now, before explaining the padding read process, a process performed to change data in a NAND flash memory is explained. For example, if the data of an already-written page in NAND flash memory 109a are partly changed based on host data received from the host system 110, the following processes must be performed. First, the data of the page to be changed are read from NAND flash memory 109a; next, the read data are changed; and finally, the newly changed data are written to an already-erased page.

In such a series of data change processes, if the host data are incomplete, a function to read a data cluster from the page to be changed of NAND flash memory 109a is defined as the above-described padding read process. Here, a page is a unit to read/write a data from/to the NAND flash memory 109.

Now, given that a predetermined LBA in the data cluster (host data) is an LBA of NAND flash memory 109a to which data have already been written, if there is a data written in the LBA (the data linked with the certain LBA), the data linked with the LBA is read from NAND flash memory 109a. That is, the data to be read is a data which corresponds to the data cluster and has been written previously to NAND flash memory 109a. In such a manner, the data for sector 1 and sector 6 can be prepared from the read data (i.e. padding read data, described later).

At that time, the data for sectors 0, 2 to 5, and 7 include two kinds of data; namely, data in the data cluster received from the host system 110, and data in the read data from NAND flash memory 109a. In this case, the data received from the host system 110 are used since they are newer than the data read from NAND flash memory 109a.

That is, if data for some sectors in a data cluster are missing as shown in data D2, the error correction code generator 106 needs the following data to generate ECC parity; a data received from the host system 110 (a first data, and hereinafter referred to as host data), and a necessary data within data corresponding to the first data which is read from NAND flash memories 109a to 109n (a second data, and hereinafter referred to as padding read data), in other words, a data in which the first data and the data of sectors not overlapping the first data are merged together (a third data, and hereinafter referred to as writeback data). Such a writeback data which allows the generator 106 to generate ECC parity is prepared using data read to pad incomplete part in the host data (padding read data) as a supplement.

FIG. 3 is a block diagram which shows an example of the structure of the error correction code generator 106 in the first embodiment.

As shown in FIG. 3, the error correction code generator 106 includes a first ECC encoder 301 which is a first encoder, second ECC encoder 302 which is a second encoder, merge buffer 303, operation part 304 which is an operation part, parity buffer for first ECC encoder (hereinafter referred to as first parity buffer) 305 which is a first buffer, parity buffer for second ECC encoder (hereinafter referred to as second parity buffer) 306 which is a second buffer, padding read data controller 307, arbitration circuit A308a, arbitration circuit B308b, and multiplexer 309.

Arbitration circuit A308a selects the data from the data buffer 103 (host data) or the data from the NAND control unit 108 (padding read data) to be sent to the first ECC encoder 301 and merge buffer 303. Only limited channels CH of the NAND controller are connected to arbitration circuit A308a, specifically, channels CH0 to CH7 (predetermined channels) among channels CH0 to CH15 are connected thereto (cf. FIG. 3).

The first ECC encoder 301 calculates ECC parity (first error correction code) relative to data to be encoded from the host system 110 (host data). More specifically, the first ECC encoder 301 calculates an intermediate value of new ECC parity from the data output from arbitration circuit A308a and an intermediate value of ECC parity held in the first parity buffer 305.

The first parity buffer 305 transmits the intermediate value of ECC parity calculated by the first ECC encoder 301 to both the first ECC encoder 301 and the operation part 304.

Arbitration circuit B308b selects the data from the data buffer 103 (host data) or the data from the NAND control unit 108 (padding read data) to be sent to the merge buffer 303 and multiplexer (MUX) 309. Only limited channels CH of the NAND controller connected to arbitration circuit B308b, specifically, channels CH8 to CH15 (remaining channels of the predetermined channels) among channels CH0 to CH15 are connected thereto (cf. FIG. 3).

The multiplexer 309 selects the data from the merge buffer 303 or the data from arbitration circuit B308b to be sent to the second ECC encoder 302.

The second ECC encoder 302 calculates, if the data (host data) from the host system 110 are incomplete (for example, data D2 as in FIG. 2), ECC parity (second error correction code) relative to the writeback data generated as complete data using the padding read data read from, for example, NAND flash memory 109a corresponding to the host data. More specifically, the second ECC encoder 302 calculates an intermediate value of new ECC parity based on the data output from the multiplexer 309 and an intermediate value of ECC parity held in the second parity buffer 306.

The second parity buffer 306 transmits the intermediate value of ECC parity calculated by the second ECC encoder 302 to both the second ECC encoder 302 and the operation part 304.

The operation part 304 operates an output result from the first parity buffer 305 (first error correction code) and an output result from the second parity buffer 306 (second error correction code) and sends the operation result to the NAND control unit 108 as finalized ECC parity. Here, the operation part 304 performs the operation to acquire the exclusive OR (XOR) of the output results from the first ECC encoder 301 and the second ECC encoder 302.

The padding read data controller 307 controls the padding read process. For example, if the padding read data controller 307 receives the host data which require the padding read process (cf. data D2 in FIG. 2) from the host system 110 through the host interface 102 and the data buffer 103, the padding read data controller 307 then transfers the host data to the merge buffer 303.

The merge buffer 303 receives the padding read data from the NAND control unit 108 through arbitration circuit A308a or arbitration circuit B308b, and merges the received data and the host data which require the padding read process together. Through this process, the writeback data suitable for generating ECC parity can be arranged.

Now, a process to calculate ECC parity performed in the first ECC encoder 301 and the second ECC encoder 302 is explained.

The first ECC encoder 301 and the second ECC encoder 302 are, for example, RS code generators corresponding to data inputs in no particular order, and hold the intermediate value of the code generation in the first parity buffer 305 and the second parity buffer 306, respectively. Here, the same structure is given to the first ECC encoder 301 and the second ECC encoder 302.

Considering a case where the first ECC encoder 301 generates ECC parity, it generates an intermediate value of new ECC parity based on the intermediate values of ECC parity held in the first parity buffer 305 and one data input by the data buffer 103 (for example, data for one logic page). The intermediate value of ECC parity at the time when the data input by the data buffer 103 has completed is used as finalized ECC parity. Note that the initial value of the intermediate value of ECC parity may be 0. The second ECC encoder 302 generates ECC parity in a similar manner as explained above and its detailed explanation is omitted.

As can be understood from the above, new ECC parity is calculated one after another based on the input data and the intermediate values of ECC parity in order to generate ECC parity. Thus, if a data cluster is incomplete (cf. FIG. 2B), the intermediate value relative to the part corresponding to lacking sectors becomes different from its original intermediate value. Consequently, finalized ECC parity becomes different. Considering this point, the padding read process must be performed when a data cluster is incomplete.

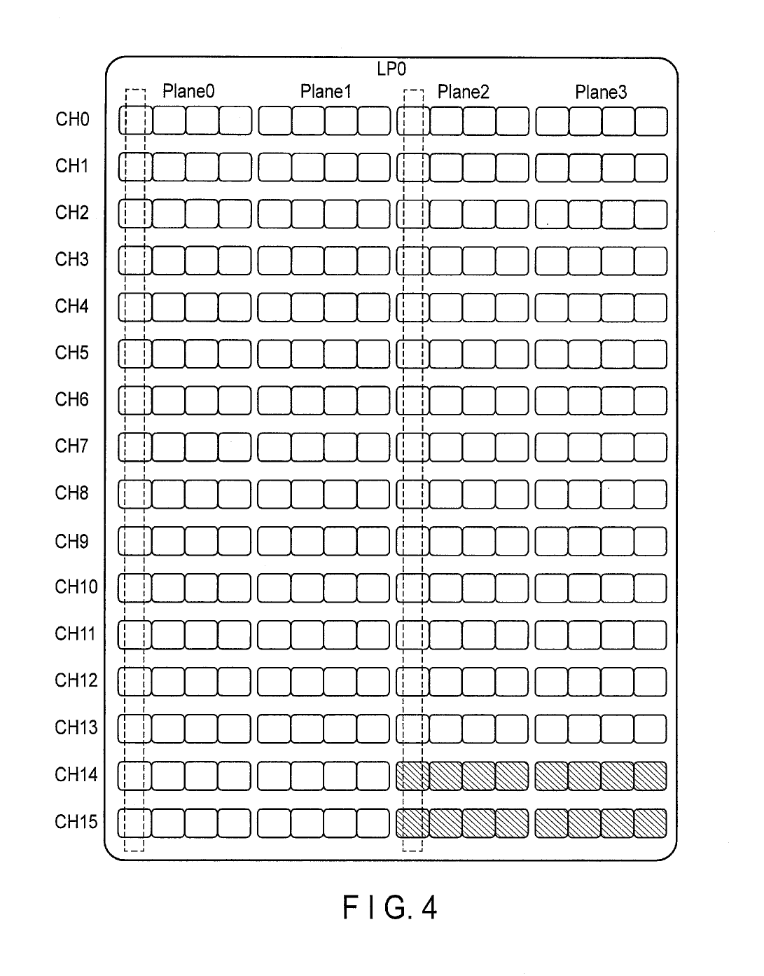

FIG. 4 shows an example of data for a single logic page stored in NAND flash memories 109a, 109b, . . . , 109n.

In FIG. 4, one square corresponds to one data cluster. One logic page is composed of sixteen channels (channels CH0 to CH15) aligned longitudinally each of which has four planes (planes 0 to 3) aligned transversely with four data clusters in each. Here, one logic page has a hierarchical structure of bytes, pages, blocks, and planes. A byte is a unit of data memory (1 or 0). A page is as explained above. A block is a unit for erasing data. A plane is a memory area and planes 0, 1, 2, and 3 are individually a set.

Furthermore, sixteen data items in planes 2 and 3 of channels CH14 and CH15 are ECC parity (error correction code). Sixteen ECC parity items are used as ECC parity for the data in the logic page, which can improve the reliability of the data in the logic page.

For example, each of the data groups marked by dotted lines in FIG. 4 (channels CH0 to CH15 of plane 0 and channels CH0 to CH15 of plane 2) indicates a single data set used to generate ECC parity. Thus, channels CH0 to CH15 of plane 0 and channels CH0 to CH13 of plane 2 can correct errors using ECC parity of channels CH14 and CH15. Furthermore, a NAND controller can access the single data set in parallel.

Next, how the error correction code generator 106 functions to generate ECC parity is explained.

If the padding read data controller 307 determines that host data from the host system 110 needs to be subjected to the padding read process, the merge buffer 303 holds the host data temporarily.

On the other hand, if the padding read data controller 307 determines that there is no need for a padding read process, arbitration circuit A308a sequentially transmits data clusters to the first ECC encoder 301. After all of data clusters for one logic page (data sets to generate the same ECC parity) have been transmitted, ECC parity is ready in the first parity buffer 305.

The merge buffer 303 merges the padding read data read from the NAND flash memory 109 for the padding read process with the host data to be padded. Through this process, the writeback data suitable for generating ECC parity is prepared. ECC parity is generated using the writeback data and stored in the second parity buffer 306.

Now, if padding read data are required from channels CH0 to CH7 in the NAND controller 108, arbitration circuit B308b is used for the data from the host system 110 which do not require a padding read process by the data buffer 103, and arbitration circuit A308a is used again at the time when the padding read process has been done.

Then, the operation part 304 acquires the exclusive OR based on ECC parity prepared in the first parity buffer 305 and the second parity in the second parity buffer 306.

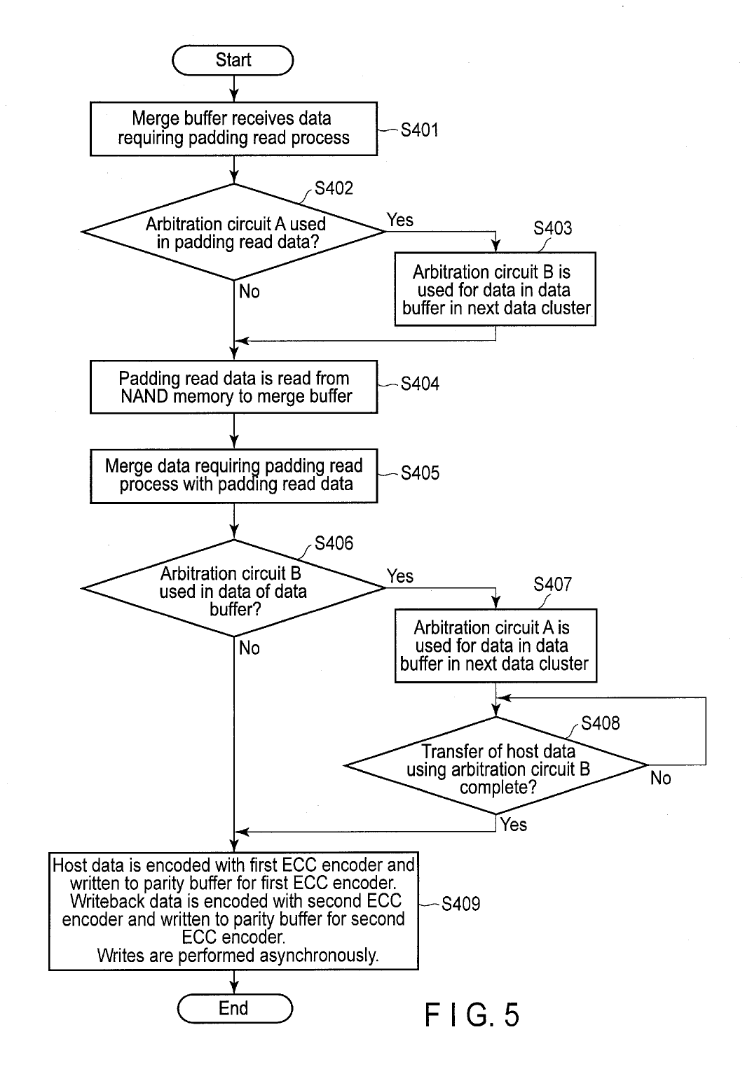

Next, a generating process of ECC parity is explained. FIG. 5 is a flowchart showing an example of a generating process of ECC parity relative to data which require a padding read process.

Firstly, host data which require a padding read process (cf. data D2 in FIG. 2) from the data buffer 103 are received in the merge buffer 303 (S401).

Secondly, the padding read data controller 307 determines whether or not padding read data use arbitration circuit A308a (S402). This determination is performed based on which channel CH has been used to read data from the NAND control unit 108. In the first embodiment, whether or not arbitration circuit A308a should be used is determined based on whether or not channels CH0 to CH7 are used.

If the padding read data uses arbitration circuit A308a (Yes in S402), the padding read data controller 307 switches the path such that the next data cluster from the data buffer 103 uses arbitration circuit B308b (S403). Through this process, the host data from the data buffer 103 use arbitration circuit B308b.

If the padding read data do not use arbitration circuit A308a (No in S402), or if the path is switched in step S403 to use arbitration circuit B308b, the padding read data controller 307 reads, for example, the padding read data from NAND flash memory 109a to the merge buffer 303 (S404).

Then, the merge buffer 303 receives the padding read data read from NAND flash memory 109a from the NAND control unit 108, and merges the host data which require the padding read process with the padding read data for generating ECC parity (S405).

Next, the padding read data controller 307 determines whether or not the data from the data buffer 103 used arbitration circuit B308b (S406).

If the data used arbitration circuit B308b (Yes in S406), the padding read data controller 307 switches the path such that the next data cluster from the data buffer 103 uses arbitration circuit A308a (S407). Through this process, the host data from the data buffer 103 use arbitration circuit A308a.

Next, the padding read data controller 307 determines whether or not the transfer of the host data (data cluster) received from the host system 110, using arbitration circuit B308b, has completed (S408).

If the transfer of the host data has not yet completed (No in S408), the determination in step S408 is repeated until the transfer of the host data completes.

On the other hand, if the transfer of the host data has completed (Yes in S408), or if arbitration circuit B308b has not been used in step S406 (No in S406), the first ECC encoder 301 encodes the host data from the host system 110 and writes calculated ECC parity to the first parity buffer 305 while the second ECC encoder 302 encodes the writeback data and writes calculated ECC parity to the second parity buffer 306 (S409). The first ECC encoder 301 and the second ECC encoder 302 perform the encode operation at different timings, that is, asynchronously.

Through the above steps, ECC parity generated from the first ECC encoder 301 and the second ECC encoder 302 is operated by the operation part 304 and transmitted to the NAND control unit 108.

With the above-described error correction code generator 106 in the semiconductor memory device 100, the first parity buffer 305 and the second parity buffer 306 are prepared in the first ECC encoder 301 and the second ECC encoder 302, respectively, such that the first ECC encoder 301 and the second ECC encoder 302 can perform the encode process independently at different timings.

Furthermore, with the error correction code generator 106 including two parity buffers 305 and 306, there is no necessity of a structure in which one parity buffer exclusively stores ECC parity of data which require the padding read process and ECC parity of host data from the host system 110 which do not require the padding read process.

Therefore, the error correction code generator 106 can generate ECC parity constantly for the host data from the host system 110 which do not require the padding read process. Moreover, even if the host data contain those which require the padding read process, the encode process can be performed without reducing the efficiency and the data can be transferred to the NAND control unit 108.

Furthermore, when ECC parity is generated and transferred to the NAND control unit 108, the data of the first parity buffer 305 and data of the second parity buffer 306 are merged (exclusive OR is acquired) in the operation part 304. Therefore, the first parity buffer 305 and the second parity buffer 306 can have an intermediate value of parity calculation individually, and lastly, the intermediate values are merged by the operation part 304 for generating the final parity result. The error correction code generator 106 can use two ECC encoders to generate ECC parity of the same set in parallel, in other words, independently.

Furthermore, in the above description of the first embodiment, the data to be encoded have been explained as the host data from the host system 110; however, the data to be encoded may be garbage collection data instead. Here, the garbage collection data refers to data relocated within a memory region to secure a successively usable memory room which is created by collecting, for example, intervening memory regions in the NAND flash memory 109. The garbage collection data are, as above, read from NAND flash memoires 109a, 109b, . . . , 109n at a predetermined timing.

If the garbage collection data are encoded, the error correction code generator 106 transmits garbage collection data read from channels CH0 to CH7 of the NAND controller 108 to the first ECC encoder 301 and garbage collection data read from channels CH8 to CH15 of the NAND controller 108 to the second ECC encoder 302.

Therefore, the error correction code generator 106 can connect channels of the NAND controller 108 shared by the first ECC encoder 301 and the second ECC encoder 302 relative to data read from the NAND control unit 108 such as padding read data and garbage collection data.

Now, given that the error correction code generator 106 simply includes two ECC encoders for an accelerated encode process, ECC parity is provided with each logic page (cf. FIG. 4) and thus, channels CH0 to CH16 of the NAND controller 108 must be connected to each of the ECC encoders 301 and 302. In contrast, the error correction code generator 106 of the first embodiment can share the channels between the first ECC encoder 301 and the second ECC encoder 302 and there is no necessity of providing channels CH0 to CH15 to each of these encoders. More specifically, the error correction code generator 106 only requires that the first ECC encoder 301 be connected with channels CH0 to CH7 and the second ECC encoder 302 be connected with channels CH8 to CH15.

Consequently, the semiconductor memory device 100 can reduce interconnections between the NAND controller 108 and the first ECC encoder 301 and the NAND controller 108 and the second ECC encoder 302 without affecting its performance.

### Second Embodiment

The semiconductor memory device of the second embodiment is different from that of the first embodiment in respects of structure and process of error correction code generator. Thus, in the following description concerning the structure and process of the error correction code generator, the technical points different from those of the first embodiments are mainly explained. Furthermore, the structures other than the error correction code generator are referred to by the same reference numbers as in the first embodiment.

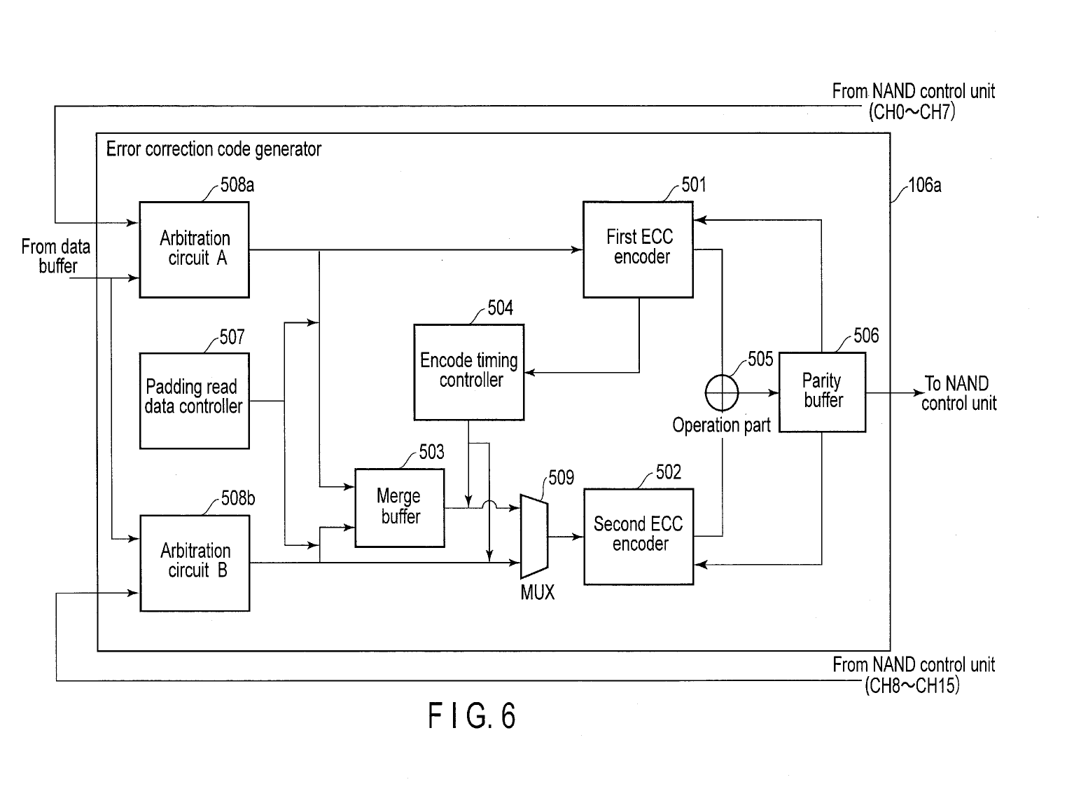

FIG. 6 is a block diagram showing an example of the structure of an error correction code generator 106a in the second embodiment.

As shown in FIG. 6, the error correction code generator 106a includes a first ECC encoder 501, second ECC encoder 502, merge buffer 503, encode timing controller 504, operation part 505, parity buffer 506, padding read data controller 507, arbitration circuit A508a, arbitration circuit B508b, and multiplexer 509.

That is, as compared to the structure of the error correction code generator 106, the error correction code generator 106a includes the encode timing controller 504 in addition, and a single parity buffer 506 instead of two parity buffers.

Note that the merge buffer 503, padding read data controller 507, arbitration circuit A508a, and arbitration circuit B508b are structured the same as the merge buffer 303, padding read data controller 307, arbitration circuit A308a, and arbitration circuit B308b in the first embodiment, respectively. Thus, their descriptions are omitted.

The first ECC encoder 501 calculates an intermediate value of new ECC parity from data output from arbitration circuit A508a and intermediate value of ECC parity held in the parity buffer 506. Furthermore, the first ECC encoder 501 transfers the calculated intermediate value to the encode timing controller 504 and the operation part 505.

The second ECC encoder 502 calculates an intermediate value of new ECC parity from data output from the multiplexer 509 and intermediate value of ECC parity held in the parity buffer 506. Furthermore, the second ECC encoder 502 transfers the calculated intermediate value to the operation part 505.

The operation part 505 acquires the exclusive OR of the values transferred by the first ECC encoder 501 and the second ECC encoder 502. Furthermore, the operation part 505 transfers ECC parity as an operation result to the parity buffer 506. Consequently, the parity buffer 506 transfers finalized ECC parity to the NAND control unit 108.

The encode timing controller 504 controls the input timing such that ECC parity calculated by the first ECC encoder 501 and ECC parity calculated by the second ECC encoder 502 are input in the operation part 505 at the same time.

More specifically, the encode timing controller 504, at the time when transferring the writeback data suitable for the ECC parity generation process in the merge buffer 503 or the garbage collection data from the NAND control unit 108 through arbitration circuit B508b to the second ECC encoder 502, observes the condition of the first ECC encoder 301, and based on an observation result, transfers the writeback data or the data from arbitration circuit B508b to the second ECC encoder 502 at a suitable timing.

Note that the writeback data suitable for the ECC parity generation process is a data cluster with a complete sector set such as data D2 in FIG. 2. The suitable timing is a time when the first ECC encoder 501 encodes the data from arbitration circuit A508a and the second ECC encoder 502 encodes the writeback data from the merge buffer 503 or the data from arbitration circuit B508b simultaneously. That is, the output from the first ECC encoder 501 and the output from the second ECC encoder 502 reach the operation part 505 and are input therein while maintaining combinations of the encode results such that ones relative to the first data are paired and ones relative to the tenth data are paired.

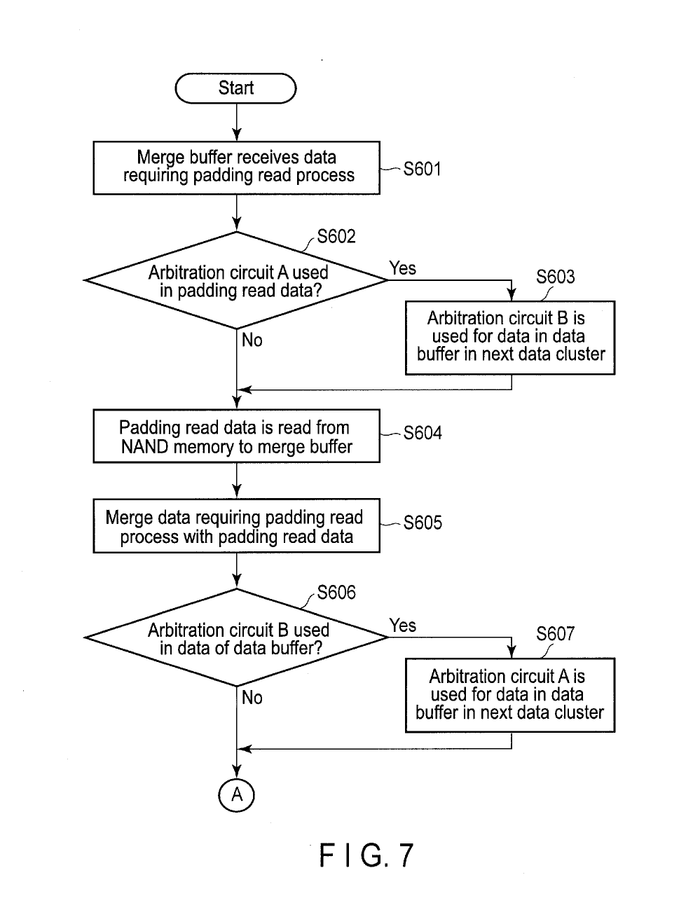

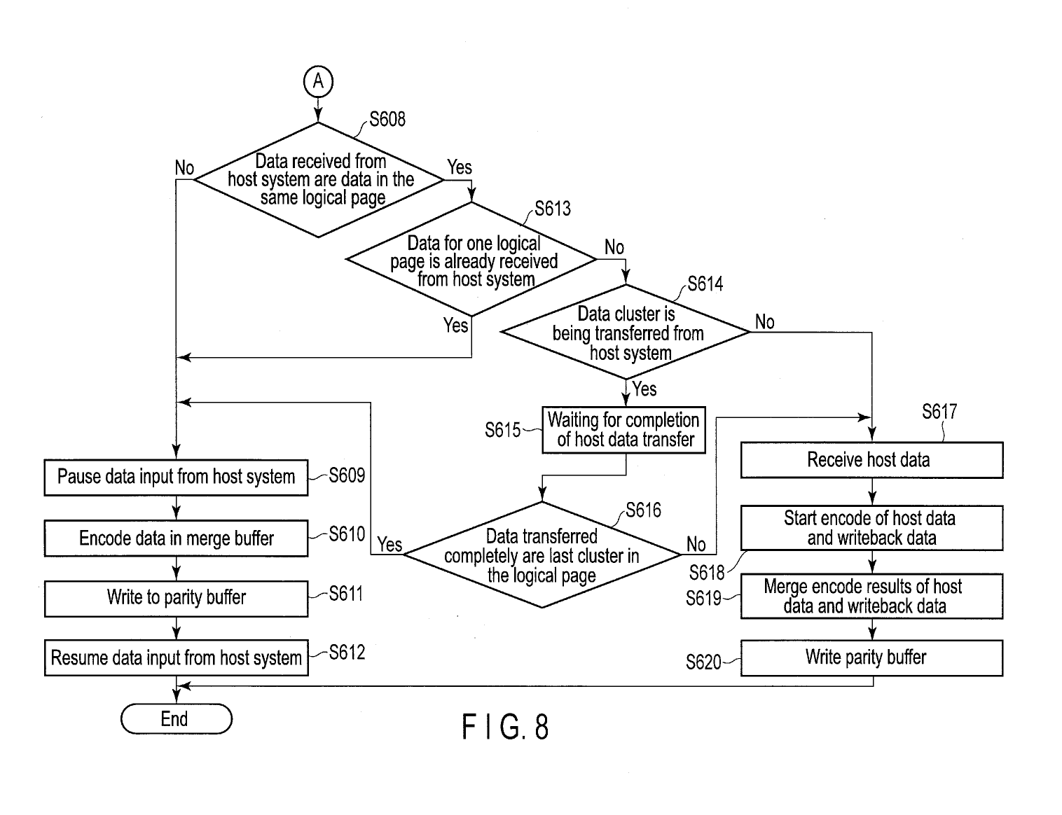

Next, the process of ECC parity generation is explained. FIGS. 7 and 8 are flowcharts each of which shows an example of the process of ECC parity generation with respect to data which require a padding read process.

Note that steps S601 to S607 are performed in the same way as steps S401 to S407 described above (cf. FIG. 5) and their detailed explanation is omitted.

Thus, hereinafter described are the steps performed if the data in the data buffer do not use arbitration circuit B508b (No in S606) and the steps performed if the data in the data buffer are switched to use arbitration circuit A508a starting from the next data cluster (S607).

As shown in FIG. 8, the padding read data controller 507 determines whether or not the same logical page includes the host data currently being received from the host system 110 and to be encoded by the first ECC encoder 501 and the writeback data from which ECC parity can be generated in the merge buffer 503 (S608). In other words, step S608 is performed to determine whether or not the host data currently being received and the writeback data in the merge buffer 503 are the data in the same logical page.

If they are not in the same logical page (No in S608), the padding read data controller 507 terminates the data reception from the host system 110, that is, the data transfer from the data buffer 103 to the first ECC encoder 501 (S609).

The second ECC encoder 502 encodes the writeback data in the merge buffer 303 to generate ECC parity and writes it to the parity buffer 506 (S611). Note that, since the data transfer to the first ECC encoder 501 has been terminated (S609); the value of ECC parity is unchanged by the operation part 505 and written to the parity buffer 506.

Next, the padding read data controller 507 restarts the data transfer from the host system 110 (data buffer 103) to the first ECC encoder 501 (S612).

This series of consecutive steps S601 to S612 is performed if host data from the host system 110 are forwarded to the process of next logical page while host data which require a padding read process are being subjected to a padding read process and ECC parity generation is being prepared.

On the other hand, if the host data to be encoded by the first ECC encoder 501 and the writeback data in the merge buffer 503 are in the same logical page (Yes in S608), the padding read data controller 507 determines whether or not the data for one logical page have been received from the host system 110 (S613). Note that, if the data for one logical page have been received from the host system (Yes in S613), steps S609 to S612 are then performed.

The series of steps S608, S613, S609, S610, S611 and S612 is performed if the host system has completed the process of the logical page currently being handled thereby when host data which require a padding read process have been subjected to a padding read process and ECC parity generation has been prepared.

If the data for one logical page from the host system 110 has not been received (No in S613), the padding read data controller 507 further determines whether or not the data cluster from the host system 110 is currently being transferred (S614).

If the data cluster is currently being transferred (Yes in S614), the padding read data controller 507 waits for the completion of the transfer of the data cluster (S615).

Next, the padding read data controller 507 determines, at the time when the transfer of the data cluster from the host system 110 has been completed, whether or not the data cluster is the last cluster in the logical page (S616).

If it is the last cluster in the logical page (Yes in S616), steps S609 to S612 are performed.

The series of steps S613, S614, S615, S616, S609, S610, S611 and S612 is performed if the data cluster of the logical page currently being handled by the host system 110 is being transferred when host data which require a padding read process has been subjected to a padding read process and ECC parity generation has been prepared.

Furthermore, in step S614, if the data cluster is not being transferred from the host system 110 (No in S614), or if the data cluster is being transferred from the host system 110 (Yes in S614) but the data cluster being transferred is not the last cluster in the logical page (No in S616), the padding read data controller 507 receives a next data cluster (host data) from the host system 110 (S617).

Next, the first ECC encoder 501 encodes the host data from the host system 110 and the second ECC encoder 502 encodes writeback data (data of the merge buffer 503) at the same time (S618).

Then, the operation part 505 merges ECC parity output from the first ECC encoder 501 and ECC parity output from the second ECC encoder 502 (S619) together, and more specifically, the operation part 505 acquires the exclusive OR of both ECC parity.

Then, the operation part 505 writes the operation result obtained in step S619 to the parity buffer 506 (S620).

The series of steps S613, S614, S617, S618, S619 and S620, or the series of steps S613, S614, S615, S616, S617, S618, S619 and S620 is performed if the host data which require a padding read process are subjected to a padding read process, ECC parity of the data which require a padding read process are generated without blocking the data flow from the host system 110, and ECC parity are merged.

Through this series of steps, the error correction code generator 106a can generate ECC parity without blocking the data flow from the host system 110 if ECC parity for the data which require a padding read process is ready to be generated before the completion of calculation of ECC parity of the logical page currently being processed.

The error correction code generator 106a described above can perform the same advantage as in the semiconductor memory device 100 in the first embodiment.

Furthermore, the error correction code generator 106a includes one less parity buffer than the error correction code generator 106 in the first embodiment. The parity buffer is composed of an expensive memory such as static random access memory (SRAM), the cost for the error correction code generator 106a can be reduced as compared to the error correction code generator 106.

As above, the first and second embodiments have been explained; however, the scope of the invention is not limited to the above embodiments. For example, the above embodiments have been explained given that the error correction code generators 106 and 106a include two ECC encoders 301 and 302 and 501 and 502, respectively; however, the number of ECC encoders is not limited to two, and three or more ECC encoders may be utilized in an error correction code generator.

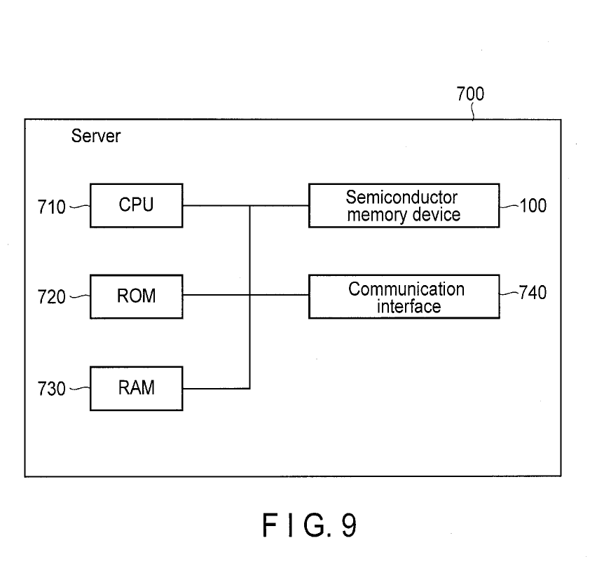

In each of the above embodiments, the semiconductor memory device 100 has been used in a memory device of the host system 110; however, this does not intend any limitation and the semiconductor memory device 100 can be used in any device with a memory device. Such a device will be, as shown in FIG. 9, a server. Note that FIG. 9 shows a schematic structure of a device (server 700) in which the semiconductor memory device 100 is incorporated. As in the Figure, the server 700 includes a CPU 710, ROM 720, RAM 730, semiconductor memory device 100, and communication interface 740.

Furthermore, the structures of the embodiments can be arbitrarily modified, altered, partly replaced and/or combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a nonvolatile memory system; and
a generator to generate an error correction code;
the generator including,
a first encoder to calculate a first error correction code with respect to a first data to be encoded,
a second encoder to calculate, if the first data is unencodable, a second error correction code with respect to a third data generated from a second data corresponding to the first data, which is read from the nonvolatile memory system, and
an operation part to operate the first error correction code and the second error correction code, and wherein
the generator generates an operation result of a predetermined unit from the operation part as the error correction code.

2. The semiconductor memory device of claim 1, further comprising:
a controller to read and write a data received from the nonvolatile memory system through a plurality of channels;
a first path to read a data from a predetermined number of channels in the plurality of channels and transfer the data to the first encoder; and
a second path to read a data from channels remaining in the plurality of channels excluding the predetermined number of channels and transfer the data to the second encoder.

3. The semiconductor memory device of claim 2, further comprising a buffer to merge the first data and the second data corresponding to the first data read from the nonvolatile memory system together, the buffer to compensate the first data with the second data corresponding to the first data to generate the third data encodable.

4. The semiconductor memory device of claim 1, wherein the operation part performs operation for acquiring exclusive OR.

5. The semiconductor memory device of claim 1, wherein the first data to be encoded is received from a host system.

6. The semiconductor memory device of claim 1, wherein the first data to be encoded is a garbage collection data.

7. The semiconductor memory device of claim 1, comprising a first buffer to transfer the first error correction code received from the first encoder to the operation part and to transfer the first error correction code to the first encoder and a second buffer to transfer the second error correction code received from the second encoder to the operation part and to transfer the second error correction code to the second encoder.

8. The semiconductor memory device of claim 1, further comprising a timing controller to control a timing of input of the first error correction code and the second error correction code to the operation part to be simultaneous.

9. The semiconductor memory device of claim 8, further comprising an interface to be connected with a host system, wherein
the timing controller controls the timing when the data received from the host system through the interface are unencodable.

10. A semiconductor memory device comprising a generator to generate an error correction code, the generator including a first encoder to calculate a first error correction code, a second encoder to calculate a second error correction code, and an operation part to operate exclusive OR from the first error correction code and the second error correction code, wherein the generator generates an operation result from the operation part as the error correction code.

11. A semiconductor memory device comprising a generator to generate an error correction code, the generator including a first encoder to calculate a first error correction code, a second encoder to calculate a second error correction code, and an operation part to operate the first error correction code and the second error correction code.
